(19) United States
(12) Patent Application Publication
(10) Pub. No.: US 2012/0250726 A1
(43) Pub. Date: Oct. 4, 2012

(54) MICRO-THERMOCOUPLE

(75) Inventor: Evgeni Sorkine, Zelenograd (RU)

(73) Assignee: TSI TECHNOLOGIES LLC, Wichita, KS (US)

(21) Appl. No.: 13/313,901

(22) Filed: Dec. 7, 2011

Related U.S. Application Data
(60) Provisional application No. 61/516,432, filed on Apr. 4, 2011.

(51) Int. Cl. G01K 7/02; H05K 13/00

(52) U.S. Cl. 374/179; 29/825; 374/E07.004

(57) ABSTRACT

Improved, high-strength micro-thermocouples (10) are provided, which include first and second microwires (12, 14) each preferably in the form of an elongated metallic core (18, 22), with an outer glass coating (20, 24); at least one of the microwires (12, 14) is an amorphous microwire (12), and in preferred forms the other microwire is a crystalline microwire (14). The thermocouple junction (16) is formed by stripping the distal ends of the microwires (12, 14) to provide stripped ends (18a, 22a). The stripped crystalline microwire end (22a) is wrapped about the stripped amorphous microwire end (18a) to form a series of abutting convolutions (30). The micro-thermocouples (10) find particular utility in the fabrication and repair of carbon fiber composite materials, such as airplane components.

### CROSS-REFERENCE TO RELATED APPLICATIONS

This application claims the benefit of provisional application Ser. No. 61/516,432, filed Apr. 4, 2011, incorporated herein by reference in its entirety.

### BACKGROUND OF THE INVENTION

1. Field of the Invention

The present invention is broadly concerned with improved micro-thermocouples of robust design fabricated using a pair of elongated metal-core microwires. More particularly, the invention is concerned with such micro-thermocouples, and methods of fabrication thereof, wherein at least one of the microwires is a high-strength, glass-coated, amorphous metallic core microwire, and the thermocouple junction comprises a spiral winding of the other microwire about the amorphous microwire.

2. Description of the Prior Art

A thermocouple is essentially a bimetal junction that provides an output voltage proportional to the temperature experienced by the thermocouple junction. Thermocouples are quite common in a multitude of uses. However, there are certain instances where thermocouples must be of extremely small size, generally referred to as micro-thermocouples. These relatively tiny thermocouples are used in a variety of settings, such as in medical devices (e.g., ablation catheters), or in temperature monitoring during fabrication or repair of composite fiber aircraft components or the like. In the latter instances, the thermocouple junctions of the micro-thermocouples are embedded into the composite materials to monitor temperatures during the curing process. The micro-thermocouples must be commensurate in size with the reinforcing fibers so as not to introduce weak points in the fabricated or repaired part. In addition, the micro-thermocouple must have sufficient mechanical strength to withstand handling, layup, and the stresses and elevated pressures developed during the fabrication or repair of the composite parts, and should also have a stable thermopower (also referred to as thermoelectric power or the Seebeck coefficient) over repeated thermal cycling. Conventional micro-thermocouples are deficient in that the thermopower EMFs thereof can vary if the thermocouples are subjected to repeated deformations during curing of composite materials.

U.S. Pat. No. 7,361,830 discloses one type of micro-thermocouple produced by removing insulation from the adjacent distal ends of at least first and second microwire electrodes, followed by forming an electrically conductive thermocouple junction at the distal ends by soldering the stripped ends using a lead-free solder, or by welding the ends together. Thereupon, the formed thermocouple junction is covered using a heat-shrinkable polymer sheath. A difficulty with this type of micro-thermocouple is that it is operable only within a restricted temperature range owing to the thermal properties of the polymeric sheath.

Another type of micro-thermocouple is described in an article entitled Double Glass Drag Spinning Method of Fabrication of Thermoelectric Coaxial Cables and Microthermocouples, Kantser et al., Journal of Optoelectronics and Advanced Materials, Vol. 8, No. 2, April 2006, pp. 601-603. This micro-thermocouple design employs a double softening glass drag spinning method with thermal furnace heating in order to fabricate long glass-coated coaxial microwires using bismuth telluride semiconductor and semi-metal cores. The resultant microwires have very high sensitivities, but the coaxial design suffers from the brittleness of the bismuth telluride material.

Other references of background interest include U.S. Pat. Nos. 5,240,066, 7,041,911, and High Frequency Properties of Glass-Coated Microwire, Antonenko et al., Journal of Applied Physics, Vol. 83, No. 11, June, 1998.

### SUMMARY OF THE INVENTION

The present invention overcomes the problems outlined above and provides greatly improved micro-thermocouples of robust design and high strength, eminently suitable for use in any context requiring a micro-thermocouple, especially in the fabrication or repair of carbon fiber composite materials. Broadly speaking, a micro-thermocouple in accordance with the invention comprises first and second elongated microwire electrodes with an electrical insulating barrier between the electrodes throughout a portion of the length thereof, with at least one of the electrodes formed of an amorphous metallic material. An electrically conductive thermocouple junction is provided between the first and second electrodes, and includes a length of one of the electrodes wrapped about the other electrode; preferably, the junction is formed at juxtaposed ends of the first and second electrodes.

In particularly preferred forms, each of the microwire electrodes is a glass-coated microwire made using the conventional Taylor-Ulitovsky process so that the metallic microwire cores has a diameter of from about 15-50 microns, more preferably from about 25-40 microns, with the glass coatings having a thickness of from about 1-10 microns, more preferably from about 2-8 microns. The microwires can have essentially any desired length, but are preferably from about 2 cm -3 m in length and are in side-by-side adjacency. In order to minimize the lateral dimensions of the micro-thermocouple, the first and second electrodes are interconnected along at least a portion of the length thereof, and preferably throughout the lengths of the glass coatings.

As noted above, at least one of the micro-thermocouple electrodes is an amorphous microwire. As used herein, “amorphous” means that the metal core is of substantially non-crystalline, undifferentiated structure, with no appreciable organization or pattern of the atoms or molecules therein, and has no more than about 10% by weight of crystalline phase therein. These types of amorphous microwires have strength, stiffness, and thermopower properties which are highly desirable in the present micro-thermocouples.

It is preferred that the other microwire forming a part of the micro-thermocouple is a substantially crystalline microwire, characterized by a substantially uniform crystalline structure throughout, with no more than about 10% by weight non-crystalline phase therein. The substantially crystalline microwire is much more readily deformable than the amorphous microwire, and therefore the stripped end of the crystalline microwire is preferably wrapped about the stripped end of the amorphous microwire to form the micro-thermocouple junction.

The formed micro-thermocouple junction may be coated with a thin layer (from about 1-10 microns) of high conductivity metal (e.g., silver, gold, or copper) and, if appropriate for a given end use, may have a thin layer of insulating material (e.g., epoxy or polyimide varnish) applied to the micro-thermocouple junction, with or without the presence of the high conductivity metal coating.

### BRIEF DESCRIPTION OF THE DRAWING

FIG. 1 is a greatly enlarged, cross-sectional view of a micro-thermocouple in accordance with the invention; and

FIG. 2 is a vertical sectional view of the micro-thermocouple of FIG. 1, illustrating the preferred thermocouple junction.

### DETAILED DESCRIPTION OF THE PREFERRED EMBODIMENT

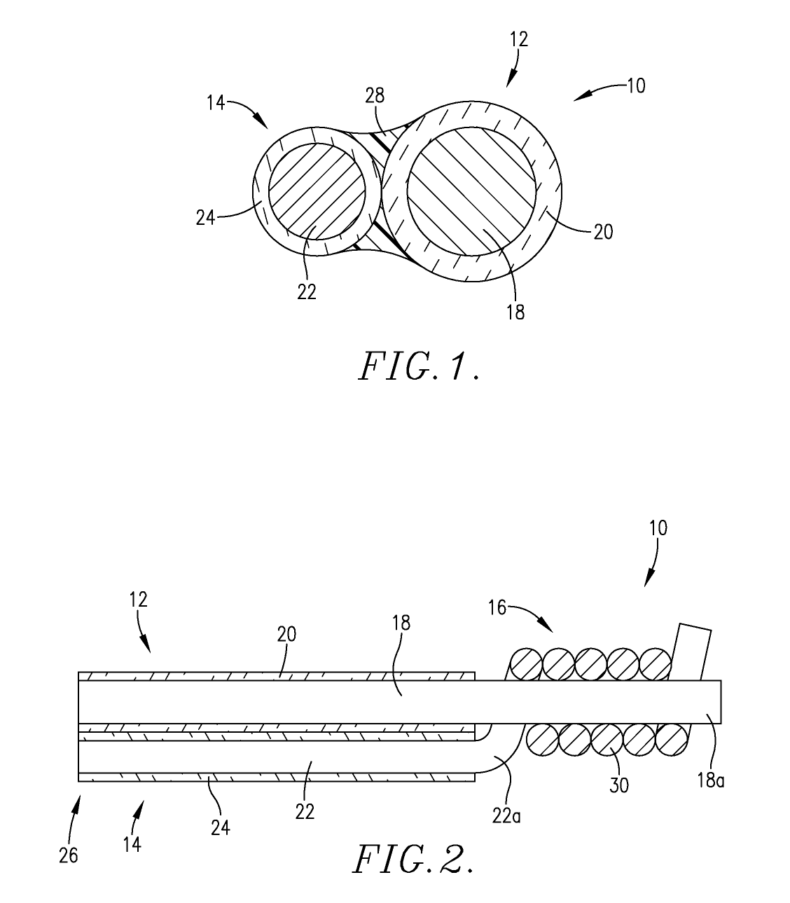

Turning now to the drawing, a preferred micro-thermocouple 10 is illustrated in FIGS. 1 and 2 and broadly includes first and second adjacent, interconnected microwires 12 and 14 and a “hot” or thermocouple junction 16 adjacent one end of the micro-thermocouple 10.

In the illustrated embodiment, the microwire 12 is formed with an elongated, metallic, amorphous core 18 and an electrically insulating glass sheath 20 about the core 18. In like manner, the microwire 14 has an elongated substantially crystalline, metallic core 22 also surrounded by an electrically insulating glass sheath 24. As illustrated, the microwires 12 and 14 are interconnected along the length thereof between the “cold” end 26 of the micro-thermocouple 10 by means of an appropriate adhesive 28, such as an epoxy or a polyimide varnish. Such an adhesive may be applied over the entire glass-coated lengths of the microwires 12 and 14, or at selected, spaced apart locations along such lengths.

The microwires 12 and 14 are advantageously fabricated using the known Taylor-Ulitovsky process by casting the molten metal core into a continuously drawn glass micro-capillary. This process is disclosed, for example, in U.S. Pat. No. 5,240,066 incorporated by reference herein in its entirety, and is applicable to the formation of both amorphous and micro-crystalline microwires. Moreover, various glass-coated microwires are commercially available, e.g., from Tamag Iberica S.L., San Sebastian, Spain, and at Microfir Tehnologii Industriale S.R.L., Chisinau, Moldava. Such microwires can be purchased with metal core diameters of from 5-110 microns, and glass coating thicknesses of 1-10 microns. The amorphous or micro-crystalline structure of the metallic cores can be fabricated using appropriate metal alloy compositions and process parameters.

The thermocouple junction 16 is formed by stripping the sheaths 20 and 24 from the corresponding microwire cores 8 and 22 to form stripped microwire ends 18a and 22a. Next, the stripped core 22a is wrapped about the stripped core 18a to provide a good electrical junction between the cores 22a, 18a. To this end, it is preferred that the stripped core 22a be wrapped so as to provide a series of tight and closely abutting convolutions 30 (preferably from about 4-10 convolutions) along the stripped core 18a. The wrapped thermocouple junction 16 may also be soldered using a lead-free solder. The formed micro-thermocouple junction 16 may be coated with a thin layer (from about 1-10 microns) of high conductivity metal (e.g. silver, gold, or copper) and, if appropriate for a given end use, may have a thin layer of electrically insulating material (e.g. epoxy or polyimide varnish) applied to said junction, with or without the presence of the high conductivity metal coating.

Stripping of the sheaths 20 and 24 to provide the core ends 18a and 22a can be accomplished mechanically or by etching the glass in a hydrofluoric acid solution. Wrapping of the core end 22a about core end 18a can be effected using a simple rotating tool made up of a fine steel tube with a narrow longitudinal slot formed therein and sized to grip the microwire end 22a.

It is particularly preferred that the microwire 12 be an amorphous glass-coated microwire. This is because such microwires have desirable mechanical properties, and especially stiffness and high tensile strengths up to 3 GPa (more than 10 times higher than that of mild steel and close to that of carbon fiber reinforced polymer compositions). Such properties are due to the substantially flawless and non-crystalline structure of the amorphous metal microwire core 18. Exemplary amorphous metallic alloys include Co-based alloys, with the addition of 15% silicon and 10% boron (both in atomic percentages). However, many other suitable alloy compositions may also be found in the art. The crystalline microwire core 22 may be cast from nickel, nickel-chromium, or copper-nickel (Constantan-type) alloys.

### EXAMPLE

A batch of micro-thermocouples in accordance with the invention were fabricated using an amorphous positive microwire electrode and a negative microwire electrode. The positive electrode was conventionally fabricated from amorphous 84 KXCP cobalt-based alloy containing iron, chromium, boron, and silicon, and had an alloy core of approximately 35 microns in diameter with a glass sheath about the core having a thickness of about 3-5 microns. The negative electrode was made of Constantan alloy (45% nickel and 55% copper) with a metal core of about 20-25 microns diameter and a glass sheath about the core having a thickness of about 5 microns. Both of these microwires were produced by Microfir Tehnologii Industriale S.R.L., Chisinau, Moldava.

The positive and negative microwire electrodes were then glued together along a length of several meters by application of a very small amount of epoxy glue. The glued microwire pair was then cut into approximately 30 cm lengths. In order to create the thermocouple junctions, the glass sheaths of both microwires were peeled off for a length of about 4-5 mm at one end thereof. The glass removal was done mechanically by using a miniature roller tool, under a 20× microscope. The tubular rotating tool described above was then used to wrap the bare negative microwire electrode around the positive microwire electrode to give a tight spiral configuration of 7-10 turns. The wrapped wire thermocouple junction was then electroplated with copper to provide an outer copper layer of about 3-5 microns in thickness.

The microwires at the opposite end of the thermocouple, remote from the thermocouple junction, were also exposed and separated, and were respectively soldered to the two pads of a conventional small printed circuit board used for connecting the micro-thermocouple to a precise digital voltmeter.

Seven of these micro-thermocouple samples were tested for consistency and stability of the generated thermal EMF when the thermocouple junctions were exposed to different temperatures. In such testing, the cold junctions of the thermocouples comprising the circuit board pads and connected microwires were maintained at ambient temperature and monitored by a standard T-type thermocouple (copper+Constantan). A digital voltmeter with 0.1 microVolt accuracy was used to measure the output voltages from the micro-thermocouples.

In the tests, the wrapped wire thermocouple junctions of each micro-thermocouple were first immersed in a thawing ice bath (0° C.), and then in a thermostat holding melted pure tin (231.93 ° C.). Stability of the thermocouples was tested by multiple heating and cooling of the wrapped wire thermocouple junctions, by alternating insertion in the molten tin and thawing ice. The consistency of the thermocouples was defined by comparing the values of total generated EMF between 0 and 231.93 ° C., for the seven fabricated samples.

The mean (0-231.93 ° C.) EMF value was found to be 6550 microVolts, with the deviations for different samples, including those subjected to repeated heating and cooling cycles, of ±15 microVolts, or 0.25%. By way of comparison, the best commercially available thermocouples produced by manufacturers such as Omega, Inc. have a 0.5% accuracy level.

I claim:

1. A micro-thermocouple comprising an elongated first microwire electrode and an elongated second microwire electrode with an electrical insulating barrier between the first and second electrodes throughout a portion of the length thereof, one of said electrodes formed of an amorphous metallic material, and an electrically conductive thermocouple junction, including a length of one of the electrodes wrapped about the other electrode.

2. The micro-thermocouple of claim 1, each of said microwire electrodes having a length of from about 2 cm -3 m, and being in side-by-side adjacency.

3. The micro-thermocouple of claim 1, each of said microwire electrodes comprising a core of metallic material with a sheath of insulating material around the core along portions of the lengths thereof.

4. The micro-thermocouple of claim 3, said core having a diameter of from about 15-50 microns, with said sheath having a thickness of from about 1-10 microns.

5. The micro-thermocouple of claim 4, said core diameter being from about 25-40 microns, with said sheath thickness being from about 2-8 microns.

6. The micro-thermocouple of claim 3, said microwire electrodes being interconnected along the lengths of said portions.

7. The micro-thermocouple of claim 6, said microwire electrodes being interconnected by an adhesive applied to said sheaths thereof.

8. The micro-thermocouple of claim 1, said second electrode being wrapped around said first electrode to form said thermocouple junction.

9. The micro-thermocouple of claim 8, said second electrode being wrapped to form a series of adjacent and abutting convolutions of said second electrode around said first electrode.

10. The micro-thermocouple of claim 8, said first electrode being said one electrode formed of amorphous metallic material.

11. The micro-thermocouple of claim 10, said second electrode being formed of a substantially crystalline metallic material.

12. The micro-thermocouple of claim 1, there being a thin layer of high conductivity metal applied to said thermocouple junction.

13. The micro-thermocouple of claim 12, said layer formed of copper, silver, or gold and having a thickness of from about 1-10 microns.

14. The micro-thermocouple of claim 1, there being a thin layer of insulating material applied to said thermocouple junction.

15. The micro-thermocouple of claim 14, said insulating material comprising epoxy or polyimide varnish.

16. The micro-thermocouple of claim 1, said thermocouple junction formed at juxtaposed ends of said first and second electrodes.

17. A method of producing a microwire thermocouple using elongated, first and second microwire electrodes having an electrical insulating barrier between the first and second electrodes along a portion of the length thereof, said method comprising the steps of:
forming an electrically conductive thermocouple junction by wrapping one of the electrodes about the other electrode,
one of said electrodes formed of an amorphous metallic material.

18. The method of claim 17, each of said microwire electrodes having a length of from about 2 cm -3 m, and being in side-by-side adjacency.

19. The method of claim 17, each of said microwire electrodes comprising a core of metallic material with a sheath of insulating material around the core along portions of the lengths thereof.

20. The method of claim 18, said core having a diameter of from about 15-50 microns, with said sheath having a thickness of from about 1-10 microns.

21. The method of claim 20, said core diameter being from about 25-40 microns, with said sheath thickness being from about 2-8 microns.

22. The method of claim 19, said microwire electrodes being interconnected along the lengths of said portions.

23. The method of claim 22, said microwire electrodes being interconnected by an adhesive applied to said sheaths thereof.

24. The method of claim 17, including the step of wrapping said second electrode about said first electrode to form said thermocouple junction.

25. The method of claim 24, including the step of wrapping said second electrode to form a series of adjacent and abutting convolutions of said second electrode around said first electrode.

26. The method of claim 24, said first electrode being said one electrode formed of amorphous metallic material.

27. The method of claim 26, said second electrode being formed of a substantially crystalline metallic material.

28. The method of claim 17, including the step of applying a thin layer of high conductivity metal to said thermocouple junction.

29. The method of claim 28, said layer formed of copper, silver, or gold and having a thickness of from about 1-10 microns.

30. The method of claim 17, including the step of applying a thin layer of insulating material applied to said thermocouple junction.

31. The method of claim 30, said insulating material comprising epoxy or polyimide varnish.

32. The method of claim 17, including the step of forming said thermocouple junction at juxtaposed ends of said first and second electrodes.
